(19) United States
(12) Patent Application Publication
(10) Pub. No.: US 2006/0215718 A1
(43) Pub. Date: Sep. 28, 2006

(54) Quantum cascade laser

(75) Inventors: Hiroaki Yasuda, Tokyo (JP); Iwao Hosako, Tokyo (JP)

Correspondence Address: C. IRVIN MCCLELLAND;OBLON, SPIVAK, MCCLELLAND, MAIER & NEUSTADT, P.C., 1940 DUKE STREET, ALEXANDRIA, VA, 22314, US

(73) Assignee: Nat. Inst. of Inf. & Comm. Tech., Inc. Admin. Agcy, Koganei-shi (JP)

(21) Appl. No.: 11/204,971

(22) Filed: Aug. 17, 2005

(30) Foreign Application Priority Data
Mar. 28, 2005 (JP) 2005-091412

(51) Int. Cl. H01S 5/00

(52) U.S. Cl. 372/45.012

(57) ABSTRACT

A quantum cascade laser is provided that is constituted as a superlattice device configured by repeatedly overlaying AlSb or GaAlSb layers and GaSb layers and forming electrode layers at the opposite ends thereof, wherein the thickness of the GaSb layers constituting quantum wells for performing stimulated emission of light is defined so that the energy difference formed between the ground state and the first excited state in the GaSb layers becomes the LO phonon energy of GaSb. The quantum cascade laser lases at lower frequency than conventionally and has a structure that is easy to fabricate.

### BACKGROUND OF THE INVENTION

1. Field of the Invention

This invention relates to a quantum cascade laser that lases in the terahertz range.

2. Description of the Prior Art

The terahertz range (1-10 THz) is a set of frequencies that are intermediate between those of infrared rays and microwave rays. This range has seen only limited utilization owing to the strong absorption of terahertz radiation by the earth's atmosphere and the lack of a small solid-state signal source. In 1994, however, the situation began to change with the invention of the quantum cascade laser (QCL), a device that makes use of inter-subband electron transition in the multi-quantum well structure of compound semiconductors. The device had a lasing frequency in the near-infrared range. Then, in 2002, development of a terahertz range QCL was reported that has since drawn attention as a small solid-state signal source usable in the terahertz range.

One example of a QCL is discussed in B. S Williams, et al., “3.4 THz quantum cascade laser based on longitudinal-optical phonon scattering for depopulation,” Applied Physics Letters, 82: 1015 (2003). This QCL has an AlGaAs/GaAs multi-quantum well structure that utilizes phonon scattering. Lasing is achieved by using the longitudinal-optical (LO) phonon scattering of GaAs to form a population inversion of electrons between the subbands. In the case of GaAs having an LO phonon energy of 36 meV, the frequency is around 3 THz. As shown in FIG. 1, the QCL is composed of repeating basic multi-quantum well structures. The basic multi-quantum well structure described in the paper of Williams et al. can be represented as 5.4/7.8/2.4/6.5/3.8/14.9/3.0/9.5 nm, where the underlined layers are barriers composed of Al_{0.15}Ga_{0.85}As and the layers that are not underlined are wells composed of GaAs. The GaAs layer of 14.9 nm thickness is n-type doped at the level of 1.9×10¹⁶ per cubic centimeter.

A brief explanation of the operating principle of the QCL follows. The subband state of the QCL's multi-quantum well structure can be determined by solving the Schroedinger and Poisson equations self-consistently. FIG. 1 shows the subband state of the conduction bands of two basic multi-quantum well structures under an applied electric field of 12.0 kV/cm. As shown in FIG. 1, each basic multi-quantum well structure is divided into an injection region and an active region. First, electrons are injected from the state 2′ or 1′ of the injection region into the excited state n=5 of the active region. Next, in the active region, the injected electrons transit from the excited state n=5 to the ground states n=4 or 3 while emitting terahertz radiation. The frequency of the radiation is determined by the energy difference between the excited state and the ground state. The energy difference between the state n=4 or 3 and the state n=2 is designed to have almost the same value as the longitudinal-optical (LO) phonon energy of the material composing the well. The phonon energy of GaAs, for example, is 36 meV Electrons in the state n=4 or 3 are therefore scattered by the LO phonons into the state n=2 to decrease the number of electrons in state n=4 or 3. The resulting population inversion is realized between the state n=5 and the state n=4 or 3. Then, laser oscillation originates. The laser frequency is designed to be 3.6 THz (15 meV).

However, in the case where the electric field strength is lower than the value used in FIG. 1 (12.0 kV/cm), the energy of the state n=4 becomes higher than those of the states n=1′ and 2′, so that the lasing process described above cannot be established and no lasing occurs.

B. S Williams, et al. have also reported a quantum cascade laser having a structure similar to the one mentioned in which the thicknesses are 5.6/8.2/3.1/7.0/4.2/16.0/3.4/9.6 nm, where the underlined layers are AlGaAs layers and the layers that are not underlined are GaAs layers (B. S. Williams, et al., Electronics Letters. Volume: 40 Issue: 7 Page 432). The thickness of the barrier at the center of the active layer is 3.1 nm and the energy difference between state 5 and state 4 is 9.0 meV to achieve 2.1 THz lasing. The barrier is 0.6 nm or a mere two atom layers thicker than that in the structure reported above, and the wells next to the barrier are a mere 0.4 and 0.5 nm thicker.

However, the foregoing two examples have the following restriction and problems.

In these examples, the thickness of the wells and barriers in the active region is less than 10 nm. The monolayer thickness of GaAs and AlGaAs is around 0.3 nm. The thickness distribution of the formed layers therefore needs to be made small. This restricts design freedom.

Moreover, the electric field strength at the start of lasing is around 12 kV/cm, which is relatively high. As a result, a large number of hot electrons and hot phonons are generated, so that deviation from the designed operation may arise and high heat generation occurs that tends to degrade the laser.

Further, these QCLs are generally fabricated using a molecular beam epitaxy (ME) machine. Since the MBE-grown layer thickness becomes more than 10 μm, layers are apt to undulate and cause local electric field concentration. When this happens, lasing occurs at the sites of high electric field concentration, while at other locations no lasing occurs but rather the produced terahertz radiation is absorbed. The laser power may be weakened as a result.

In order to form the necessary superlattice, semiconductor layers of greater thickness are used. In addition, the electric field strength at the start of lasing is set lower so as to curb degradation of the laser by abnormal operation and heat generation owing to the generation of hot electrons and hot phonons.

The present invention makes it possible to realize a quantum cascade laser having a lower lasing frequency and an easier structure to fabricate than conventional quantum cascade lasers.

### SUMMARY OF THE INVENTION

This invention provides a quantum cascade laser constituted as a superlattice device comprising AlSb or GaAlSb layers and GaSb layers repeatedly overlaid and electrode layers formed at opposite ends thereof, wherein the GaSb layers constituting quantum wells for performing stimulated emission of light has a thickness defined so that an energy difference between a ground state and an excited state in the GaSb layers becomes LO phonon-energy of GaSb.

Specifically, the superlattice device has as a repeating unit an AlSb layer, a GaSb layer, an AlSb layer, a GaSb layer, an AlSb layer, an n-type GaSb layer, an AlSb layer and a GaSb layer, a plurality of such units being sandwiched between two n-type semiconductor layers used as contact layers.

A structure in which the AlSb layers are replaced by GaAlSb also functions as a quantum cascade laser.

Terahertz radiation containment can be effectively achieved by forming the quantum cascade laser on a superlattice buffer.

Formation of the quantum cascade laser on a GaAs substrate through an intervening buffer layer permits a reference beam to be irradiated through the GaAs substrate.

The quantum cascade laser can be used for synchronized lasing. In this case, the potential difference required for lasing is applied across the electrodes and a reference beam is irradiated on the superlattice region.

### BRIEF EXPLANATION OF THE DRAWINGS

FIG. 1 is a schematic diagram showing the energy band structure of a quantum cascade laser.

FIG. 2 is a schematic diagram showing the energy band structure of a quantum cascade laser according to the invention.

FIG. 3 is an overview showing steps in the process of fabricating a quantum cascade laser according to the invention.

FIG. 4(a) is a sectional view of a quantum cascade laser according to this invention.

FIG. 4(b) is a perspective view of the quantum cascade laser of FIG. 4(a).

FIG. 5 is a diagram showing the setup in the case of injection locking.

### DESCRIPTION OF THE PREFERRED EMBODIMENT

An embodiment of the invention will now be explained in detail with 5 reference to the drawings. An embodiment of the quantum cascade laser of this invention will first be explained with reference to Table 1 below.

TABLE 1

| | | | Thickness | Te concentration |
|---|---|---|---|---|
| No. | | Material | (nm) | (cm⁻³) |
| 1 | | n-GaSb (contact | 60 | 500E+18 |
| | | layer) | | |
| 2 | ↑ | QCL structure | (1 module: | |
| | 200 | | 80.1 nm × | |
| | repeti- | | 200 times) | |
| | tions | AlSb | 4.3 | |
| | ↓ | GaSb | 14.4 | |
| | | AlSb | 2.4 | |
| | | GaSb | 11.4 | |
| | | AlSb | 3.8 | |
| | | n-GaSb | 24.6 | 1.90E+16 |
| | | AlSb | 3 | |
| | | GaSb | 16.2 | |
| 3 | | n-GaSb (contact | 800 | 3.00E+18 |
| | | layer) | | |
| 4 | ↑ 20 repeti- | Superlattice buffer | (1 module: | |
| | ↓ tions | | 5 nm × | |
| | | | 20 times) | |
| | | GaSb | 2.5 | |
| | | AlSb | 2.5 | |
| 5 | | Buffer | | |
| | | GaSb buffer | 1000 | |
| | | AlSb buffer | 100 | |
| | | AlAs buffer | 10 | |
| | | GaAs buffer | 100 | |

Semi-insulating GaAs substrate

As shown in Table 1 above, a semi-insulating GaAs substrate is used as the semiconductor substrate. Buffer layers, for example layers of GaAs (100 nm), AlAs (10 nm), AlSb (100 nm) and GaSb (1000 nm), are successively formed on the substrate using a molecular beam epitaxy (HE) machine. Further, twenty 2.5 nm AlSb layers and twenty 2.5 nm GaSb layers are alternately formed as additional buffer layers. Next, a first contact layer composed of n+ GaSb doped with n-type impurity at, for example, 3×10¹⁸/cm³ is formed to a thickness of about 800 nm. Next, a basic multi-quantum well structure composed of, in top-down order, of 4.3/14.4/2.4/11.4/3.8/24.6/3.0/16.2 nm layers, where the underlined layers are barriers composed of AlSb and the layers that are not underlined are wells composed of GaSb, is formed. The structure thus has a 16.2 nm GaSb layer on its substrate side. The GaSb layer of 24.6 nm thickness is n-type doped at the level of 1.9×10¹⁶/cm³. Electrons are supplied from this n-type layer and scattering occurs. This basic multi-quantum well structure is repeatedly formed 200 times, for example. A second contact layer composed of GaSb doped with n-type impurity at, for example, 5×10¹⁸/cm³ is then formed to a thickness of, for instance, 60 nm. The compound semiconductors following the buffer layers are also formed using an MBE machine.

Antimony-based compound semiconductors such as GaSb tend to disperse on the surface during MBE growth. Surface irregularities can therefore be suppressed to minimize electric field concentration when voltage is applied. The laser beam is therefore more uniformly generated and the laser intensity increases because the terahertz radiation is not readily absorbed at places other than the electric field concentration sites.

The fabrication process of the QCL having the foregoing structure will now be explained.

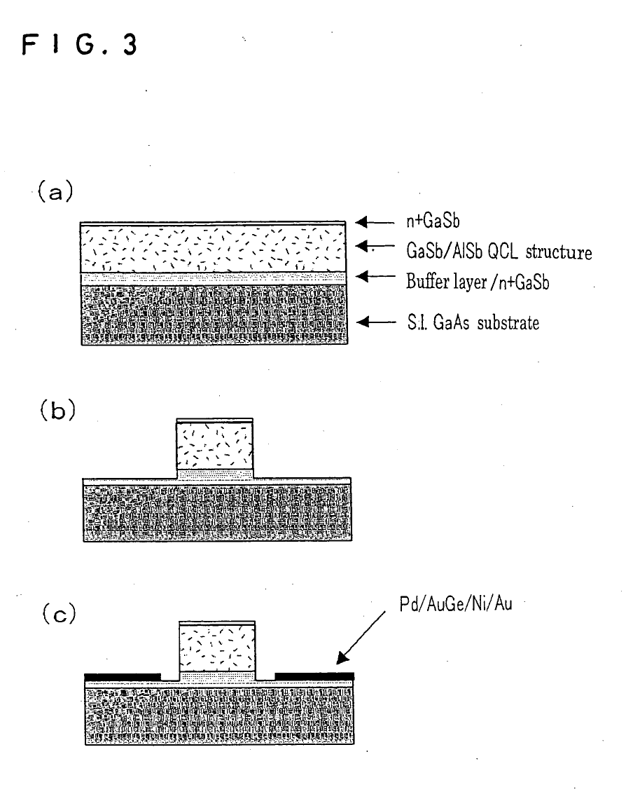

1) In FIG. 3, the upper diagram (a) shows a partial sectional view of the wafer immediately after MBE growth. First, the resist on the portions to become the ridge structures of the QCL are selectively allowed to remain.

2) Then, using the resist as a mask, the multi-quantum well structure is removed by reactive ion etching (RIE) using SiCl₄, for example, to selectively expose the first contact layer.

3) After removal of the resist ((b) in FIG. 3), a metal layer of, for example Pd/AuGe/Ni/Au is selectively formed on the exposed first contact layer by the liftoff method. A sectional view of the structure at this stage of fabrication is shown at (c) in FIG. 3.

4) Annealing is then conducted at, for example, 300° C. for one minute.

5) Next, a metallic layer of, for example, Pd/Au is selectively overlaid on the upper surface of the mesa structure formed by RIE, i.e., on the second contact layer, by the liftoff method.

6) The wafer is then cleaved to form a resonator of approximately 2 mm length. The width of the ridge structure is in the approximate range of 100 μm to 200 μm.

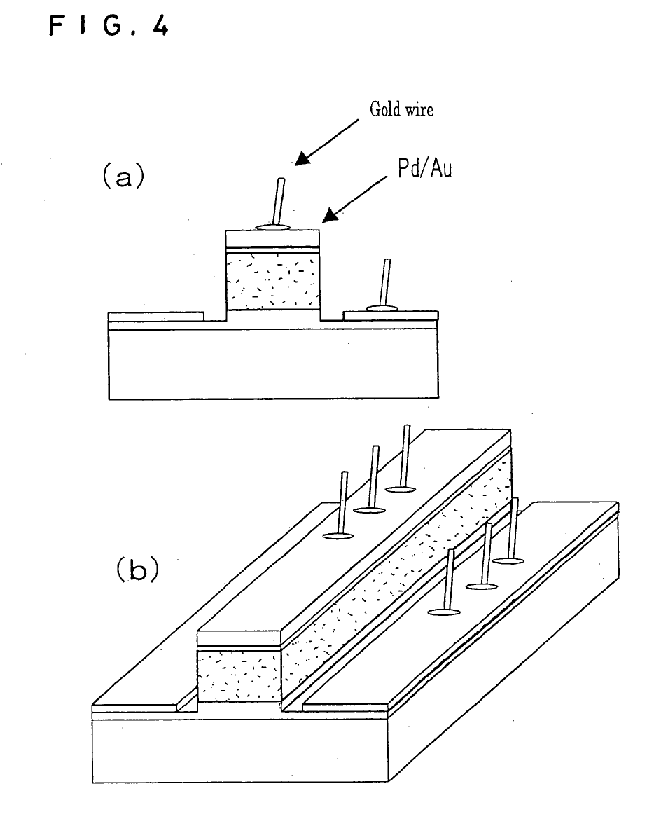

7) Gold wires are attached to the electrodes on the first contact layer and the second contact layer, thereby forming two leads. FIG. 4(a) and 4(b) are a sectional view and a perspective view of the structure at this stage of fabrication.

8) The so-fabricated device is operated by applying a voltage across the leads, i.e., across the electrodes. If necessary, the QCL is cooled with liquid nitrogen or liquid helium and a pulsed voltage is applied.

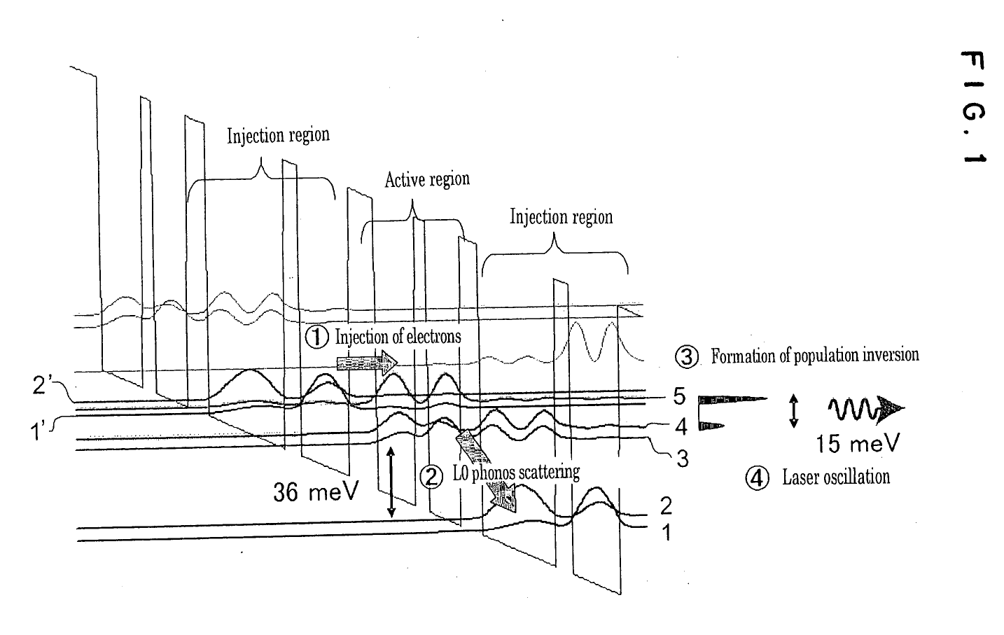

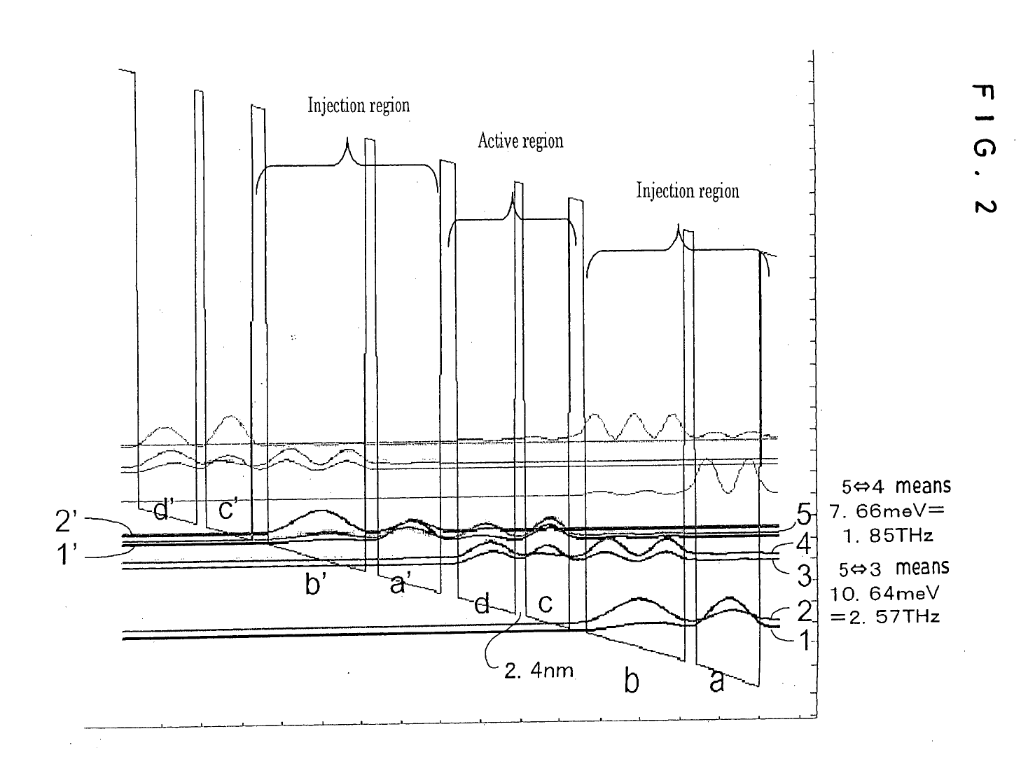

FIG. 2 shows the subbands in the conduction band for two basic structure units of the QCL configuration of the foregoing embodiment. Each interval on the vertical axis corresponds to 10 meV and each interval on the horizontal axis to 10 nm. The subbands are determined by solving the Schroedinger and Poisson equations self-consistently in one dimension. In FIG. 2, the subbands are represented as what is obtained by multiplying the probability density in the state, i.e. the square of the wave function, by an appropriate multiple for convenience of representation and adding the product to the energy in the state. The sum of the subband probability density is normalized to 1. The wells a, b, c and d are GaSb layers having thicknesses of 16.2 nm, 24.6 nm, 11.4 nm and 14.4 nm, respectively. The electric field strength in FIG. 2 is 5.45 kV/cm, which is less than half the value in FIG. 1. The energy difference between state 5 and state 4 is 7.66 meV, corresponding to 1.85 THz, and the energy difference between state 5 and state 3 is 10.64 meV, corresponding to 2.57 THz. Thus, the QCL of this embodiment achieves lasing at a lower frequency than the conventional QCL of FIG. 1 notwithstanding that the thickness of the barrier between the well c and well d is 2.4 nm in both QCLs. Moreover, the QCL of this embodiment enjoys greater design freedom than the conventional QCL owing to the greater thickness of the wells.

The design principles of the QCL structure will now be explained and a preferred structure of the invention QCL described.

First, regarding to the active region, the thicknesses of the well c, the well d and the barrier therebetween are designed to establish the ground state and the excited state in the well c and the well d and make the energy difference between the states approximately equal to the lasing frequency of the QCL at a prescribed lasing electric field strength. So as to make the wave functions of the ground state and excited state present in both the well c and the well d, the ground state wave function is made to arise chiefly from the well d and the excited state wave function is made to arise chiefly from the well c. In other words, the well c is made narrower than the well d.

Next, regarding the injection region, LO phonon scattering of electrons from state 4 or 3 to state 2 or 1 is necessary in FIG. 2. For this, the thickness of the well b is defined so that at a prescribed electric field strength, e.g., at the electric field strength at which lasing starts, the energy difference between the ground state and the excited state in the well b becomes equal to the LO phonon energy of GaSb. The phonon energy of GaSb is around 28.9 meV and is thus characterized in being smaller than in the conventional QCL.

Further, at the prescribed electric field strength, for efficient extraction of the phonon-scattered electrons from the well b into the well a, the thickness of the well a and the thickness of the barrier between the wells a and b are defined so that, as shown in FIG. 2, the ground state energy of the well b and the ground state energy of the well a are about the same. In light of the fact that the ground state energy increases with decreasing well thickness, the well a is made thinner than the well b.

Further, regarding the relationship between the active region and the injection region, efficient injection of electrons from the well a′ into the first excited state of the well d or well c is enabled by making the energy levels of the injection region ground state and the active region first excited state about the same at a prescribed electric field strength, thereby coupling their wave functions.

In addition, efficient extraction of electrons from the ground state of the active region at the prescribed electric field strength is enabled, i.e., coupling of the ground state of the well c or well d with the first excited state in the well b is established. The thicknesses of the well c and well d are made about half that of the thickness of the well b.

As can be seen from the foregoing conditions, the electric field strength and the well and barrier thicknesses are regulated and calculation repeated. From this it can be seen that the sum of the thickness of the well a′, well c and well d is made not greater than twice the thickness of the well b.

Further, when the prescribed electric field strength is applied, there must arise in each basic unit of the QCL a potential difference approximately the same as the energy sum of an energy difference between the excited state and the ground state in the injection region, i.e., the LO phonon energy and an energy difference between the excited state and ground state energies in the active region, i.e., the energy corresponding to the lasing frequency. As explained in the foregoing, the thickness of the wells a to d are substantially defined, so that this condition must be met by varying the electric field strength. Therefore, by making the LO phonon energy small as in this invention, it is possible to lower the electric field strength at which lasing starts.

Moreover, when the LO phonon energy is small as in this invention, the width of the well b becomes large so that the thickness of the other wells and barriers can be made large. Further, owing to the fact that the effective mass of GaSb is 0.0412 and smaller than the effective mass of 0.67 of GaAs, the use of GaSb as in this invention enables the width of the wells to be made larger As a result, the effect that a thickness fluctuation of one atom layer has on laser performance, e.g, the lasing frequency, is small. MBE growth is therefore easier because the allowable range of film thickness during film growth by MBE becomes greater.

In addition, use of the aforesaid antimony-based MBE growth minimizes surface undulations to enable increase in laser power.

This invention thus increases the degree of design freedom and enables lowering of the lasing frequency.

Although use of AlSb for the barrier layers is exemplified in the foregoing embodiment, no reason exists for limiting the compound to AlSb and any of various other compounds that constitute a barrier with respect to GaSb and readily form a superlattice structure can be used instead. For example, there can be used GaₓAl₁₋ₓSb (where x is a value between 0 and 1). Moreover, since AlSb layers or GaAlSb layers can be used as barriers, mixed use thereof is also possible.

The invention can utilize a waveguide of surface plasmon mode structure on one side. However, the invention is not limited to this type of waveguide and can use a metal-metal waveguide instead. In addition, containment of the generated terahertz radiation within the QCL structure can be achieved by providing contact layers of high impurity concentration above and below the QCL structure so as to control the refraction index. However, the invention is not limited to this arrangement and it is obviously possible to provide a layer having a low index of refraction instead.

Synchronous lasing of the QCL can be achieved by injection of a reference beam as follows.

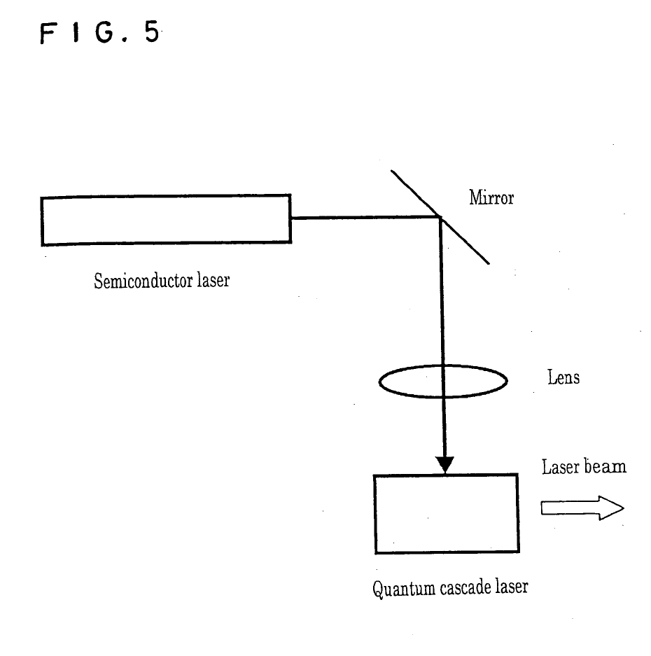

When, for example, it is desired to lock the lasing frequency of the QCL by injection of a semiconductor laser beam in the 1.5 micron band (injection locking), a pulsed laser beam is injected using the configuration shown in FIG. 5. In the case of the foregoing embodiment, however, the semiconductor laser beam would be reflected because the upper electrode of the QCL is made of gold or other metal. On the other hand, injection locking by use of a 1.5 micron laser, for example, is impossible when the substrate of the QCL is made of GaSb because GaSb absorbs radiation up to the long wavelength side. In contrast, when a substrate, such as a GaAs substrate, as in the foregoing embodiment is used, such absorption does not occur, whereby it becomes possible to achieve injection locking of the QCL from the rear of the substrate, for example, using a 1.5 micron band semiconductor laser. It should be noted, however, that the semiconductor laser beam can be injected not only from the substrate side but also through the side faces of the ridge structures or from above if the electrodes of the QCL are made from a transparent material such as iridium-tin-oxide (ITO).

What is claimed is:

1. A quantum cascade laser constituted as a superlattice device comprising AlSb or GaAlSb layers and GaSb layers repeatedly overlaid and electrode layers formed at opposite ends thereof, wherein the GaSb layers constituting quantum wells for performing stimulated emission of light has a thickness defined so that an energy difference formed between a ground state and a first excited state in the GaSb layers becomes LO phonon energy of GaSb.

2. A quantum cascade laser according to claim 1, wherein the superlattice device has as a repeating unit an AlSb layer, a GaSb layer, an AlSb layer, a GaSb layer, an AlSb layer, an n-type GaSb layer, an AlSb layer and a GaSb layer, a plurality of such units being sandwiched between two n-type semiconductor layers used as contact layers.

3. A quantum cascade laser according to claim 1, wherein the superlattice device has as a repeating unit a GaAlSb layer, a GaSb layer, a GaAlSb layer, a GaSb layer, a GaAlSb layer, an n-type GaSb layer, a GaAlSb layer and a GaSb layer, a plurality of such units being sandwiched between two n-type semiconductor layers used as contact layers.

4. A quantum cascade laser according to claim 2, further comprising a superlattice buffer on which it is formed.

5. A quantum cascade laser according to claim 3, further comprising a superlattice buffer on which it is formed.

6. A quantum cascade laser according to claim 2, further comprising a GaAs substrate on which it is formed through an intervening buffer layer.

7. A quantum cascade laser according to claim 3, further comprising a GaAs substrate on which it is formed through an intervening buffer layer.

8. A quantum cascade laser according to claim 4, further comprising a GaAs substrate on which it is formed through an intervening buffer layer.

9. A quantum cascade laser according to claim 5, further comprising a GaAs substrate on which it is formed through an intervening buffer layer.

10. A quantum cascade laser according to claim 1, wherein a potential difference required for lasing is applied across the electrode layers and a reference beam is irradiated on a superlattice region.

11. A quantum cascade laser according to claim 2, wherein a potential difference required for lasing is applied across the electrode layers and a reference beam is irradiated on a superlattice region.

12. A quantum cascade laser according to claim 3, wherein a potential difference required for lasing is applied across the electrode layers and a reference beam is irradiated on a superlattice region.

13. A quantum cascade laser according to claim 4, wherein a potential difference required for lasing is applied across the electrode layers and a reference beam is irradiated on a superlattice region.

14. A quantum cascade laser according to claim 5, wherein a potential difference required for lasing is applied across the electrode layers and a reference beam is irradiated on a superlattice region.

15. A quantum cascade laser according to claim 6, wherein a potential difference required for lasing is applied across the electrode layers and a reference beam is irradiated on a superlattice region.

16. A quantum cascade laser according to claim 7, wherein a potential difference required for lasing is applied across the electrode layers and a reference beam is irradiated on a superlattice region.

17. A quantum cascade laser according to claim 8, wherein a potential difference required for lasing is applied across the electrode layers and a reference beam is irradiated on a superlattice region.

18. A quantum cascade laser according to claim 9, wherein a potential difference required for lasing is applied across the electrode layers and a reference beam is irradiated on a superlattice region.
